(19) United States
(12) Patent Application Publication
(10) Pub. No.: US 2007/0048920 A1
(43) Pub. Date: Mar. 1, 2007

(54) Methods for dual metal gate CMOS integration

(75) Inventors: Seung-Chul Song, Austin, TX (US); Zhibo Zhang, Austin, TX (US); Byoung Hun Lee, Austin, TX (US); Naim Moumen, Walden, NY (US); Joel Barnett, Austin, TX (US); Muhammad Mustafa Hussain, Austin, TX (US); Rino Choi, Austin, TX (US); Husam Alshareef, Austin, TX (US)

Correspondence Address: FULBRIGHT & JAWORSKI L.L.P., 600 CONGRESS AVE., SUITE 2400, AUSTIN, TX, 78701, US

(73) Assignee: SEMATECH

(21) Appl. No.: 11/212,127

(22) Filed: Aug. 25, 2005

(51) Int. Cl. H01L 21/8238; H01L 21/8234; H01L 21/4763; H01L 21/3205

(52) U.S. Cl. 438/199; 438/275; 438/229; 438/592; 438/585

(57) ABSTRACT

Methods for fabricating two metal gate stacks for complementary metal oxide semiconductor (CMOS) devices are provided. A first metal layer may be deposited onto a gate dielectric. Next a mask layer may be deposited on the first metal layer and subsequently etch. The first metal layer is then etched. Without removing the mask layer, a second metal layer may be deposited. In one embodiment, the mask layer is a second metal layer. In other embodiments, the mask layer is a silicon layer. Subsequent fabrication steps include depositing another metal layer (e.g., another PMOS metal layer), depositing a cap, etching the cap to define gate stacks, and simultaneously etching the first and second gate region having a similar thickness with differing metal layers.

### BACKGROUND OF THE INVENTION

1. Field of the Invention

The present invention relates generally to semiconductor fabrication, and more particularly to a method for fabricating dual metal gate complementary metal oxide semiconductor (CMOS) devices.

2. Description of Related Art

Semiconductor devices are continuously improved to enhance device performance. For example, smaller device sizes allow for the ability to construct smaller gate structures for complementary metal oxide semiconductor (CMOS) transistors such that more transistors are fitted on the same surface area, improving the switching speed of the transistor among other benefits. With CMOS technology scaling to approximately 45 nm or less, the conventional poly-silicon dioxide gate stack is reaching its scaling limitation. Issues such as power, dissipation, and tunneling become more prevalent when the vertical dimension is reduced, e.g., decreasing the thickness of the poly-SiO₂ gate dielectric.

One alternative to the poly-SiO₂ gate stack is a metal gate, particularly a dual metal gate stack. Dual metal gate stacks generally require two separate metals, one metal over the NMOS active area and the other over the PMOS active region. These two metals may be selected based on their workfunction and ease of integration during wet and/or dry etch processes.

A conventional method for integrating dual metal gate CMOS includes depositing a first metal onto an NMOS and PMOS active region. The first metal layer can be an NMOS metal or PMOS metal depending on, for example, the ease of removal and selectivity without damaging the underlying gate dielectric. Usually, the NMOS metal (e.g., TaSiN, TiN, TaN, or the like) has a workfunction close to a silicon conduction band and exhibits more tendency of dissolution in common wet etch chemistries such as, but not limited to, SPM, SC1, or H₂O₂. PMOS metals (e.g., Ru, MO, W, Pt) have a workfunction similar to a silicon valence band and are more inert and difficult to etch in wet chemistries that are typically used in normal microelectronic fabrication. Thus, due to the ease of the etching process, NMOS metal is usually the first metal deposited and subsequently etched using known techniques in the art. Next, the second metal layer is deposited, generally on both the PMOS region and NMOS region.

As known in the art, due to the nature of the etching process, primarily for removing a metal layer without damaging the underlying gate dielectric, lithography process involves using a masking material to block an etching process over an area. For example, if an NMOS metal is first deposited, the masking material would allow for the metal to be removed from the PMOS area while blocking etching in the NMOS area.

One example of a masking layer is a photoresist layer. However, normal metal etch chemistry, particularly an NMOS metal etch chemistry including, without limitation, SPM, SC1, or H₂O₂, tends to also etch the photoresist layer at a high etch rate. The etching of the masking layer makes it difficult to preserve the metal layer on the active region, e.g., an NMOS metal on an NMOS region or a PMOS metal on a PMOS region.

Other materials such as oxides or nitrides have been used as masking material. In the case where an NMOS material is deposited as a first metal layer, both oxides and nitrides serving as a masking layer are not affected by the etching process, allowing the NMOS metal to be selectively removed in the PMOS region. However, prior to the deposition of the PMOS metal, the oxides or nitrides masking material needs to be removed. Typically, hydrofluoric (HF) acid can be used to remove an oxide masking layer, but the HF can damage the gate dielectric layer by etching it. Similarly, the removal of a nitride masking layer may cause similar damages to the gate dielectric. Damages to the gate dielectric can cause many problems including device failure, reduction in yield, and higher production cost.

Additionally, complications may arise from the simultaneous patterning of two gate stacks that are different in thickness and composition. For example, an NMOS gate stack may include two metal layers and a poly layer as compared to the PMOS gate stack which may include only one metal layer and a poly layer. Subsequent fabrication processes, such as an anneal process may cause the two metal layers in the NMOS gate stack to intermix. Any of the above complications may contribute to device failure and other issues.

Any shortcoming mentioned above is not intended to be exhaustive, but rather is among many that tends to impair the effectiveness of previously known techniques for fabricating a dual metal gate stack; however, shortcomings mentioned here are sufficient to demonstrate that the methodologies appearing in the art have not been satisfactory and that a significant need exists for the techniques described and claimed in this disclosure.

### SUMMARY OF THE INVENTION

By replacing the poly gate electrodes with a dual work function metal gate electrode, issues such as polysilicon depletion can be reduced or substantially eliminated and inversion capacitance can be increased as compared to standard polysilicon/SiO₂ gate. Particularly, the present disclosure describes an integration method that minimizes or substantially eliminates the impact on an underlying gate dielectric layer upon removing or, etching of a first and second metal layer.

In one respect, the disclosure involves a method for fabricating metal gate stacks. The method may include providing a substrate comprising two active areas (an NMOS active region and a PMOS active region) and a gate dielectric layer. Next, a first metal may be deposited over the gate dielectric to form a first metal layer, followed by a deposition of a second metal to form a second metal layer. In one embodiment, the first metal may include, by example, TaSiN, TiN, or TaN to form a NMOS metal layer. The second metal may include, by example, Ru, MO, W, or Pt to form a PMOS metal layer.

Next, the method provides a step for depositing a photoresist layer onto the second metal layer. In one embodiment, the photoresist layer may be deposited over the NMOS active region. Next, the second metal may be selectively etched, for example, the second metal may be etched in the PMOS active region. Subsequent steps may include removing the photoresist layer.

Without removing the second metal layer, the method provides steps for etching the first metal layer. In this embodiment, the second metal layer serves as a masking layer during the etching process of the first metal layer.

Other features and associated advantages will become apparent with reference to the following detailed description of specific embodiments in connection with the accompanying drawings.

### BRIEF DESCRIPTION OF THE DRAWINGS

The following drawings form part of the present specification and are included to further demonstrate certain aspects of the present invention. The figures are examples only. They do not limit the scope of the invention.

FIG. 1 shows a flowchart of a method for integrating dual metal gate stacks, in accordance with embodiments of this disclosure.

FIG. 2 shows a flowchart of a method for integrating dual metal gate stacks, in accordance with embodiments of this disclosure.

FIG. 3 shows a flowchart of a method for integrating dual metal gate stacks, in accordance with embodiments of this disclosure.

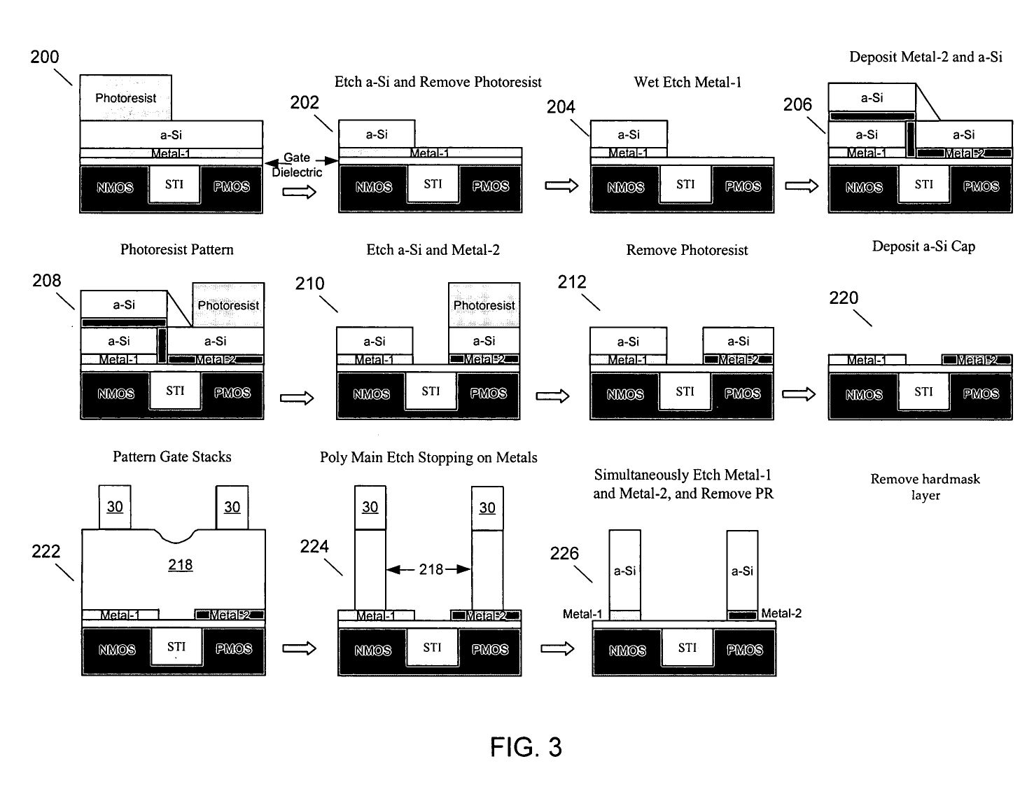

### DESCRIPTION OF ILLUSTRATIVE EMBODIMENTS

The disclosure and the various features and advantageous details are explained more fully with reference to the nonlimiting embodiments that are illustrated in the accompanying drawings and detailed in the following description. Descriptions of well known starting materials, processing techniques, components, and equipment are omitted so as not to unnecessarily obscure the invention in detail. It should be understood, however, that the detailed description and the specific examples, while indicating embodiments of the invention, are given by way of illustration only and not by way of limitation. Various substitutions, modifications, additions, and/or rearrangements within the spirit and/or scope of the underlying inventive concept will become apparent to those skilled in the art from this disclosure.

The disclosure provides methods for fabricating dual metal gate structures on a CMOS device while minimizing the impact of etching processes on an exposed gate dielectric. Particularly, the present disclosure provides a mask layer that has good selectivity to a first metal layer and a gate dielectric containing silicon dioxide. In some embodiments, the mask layer includes a metallic masking material, which eliminates the step to remove a masking material before the deposition of a second metal layer, which is desirable since the process reduces the number of material in a gate stack.

The disclosure also provides methods for fabricating dual metal gate structures on a CMOS device while minimizing the impact of etching processes on an exposed gate dielectric. Additionally, the gate stacks in the NMOS and PMOS regions may have similar heights and composition, thus making the simultaneous etching process of the gate stacks easier.

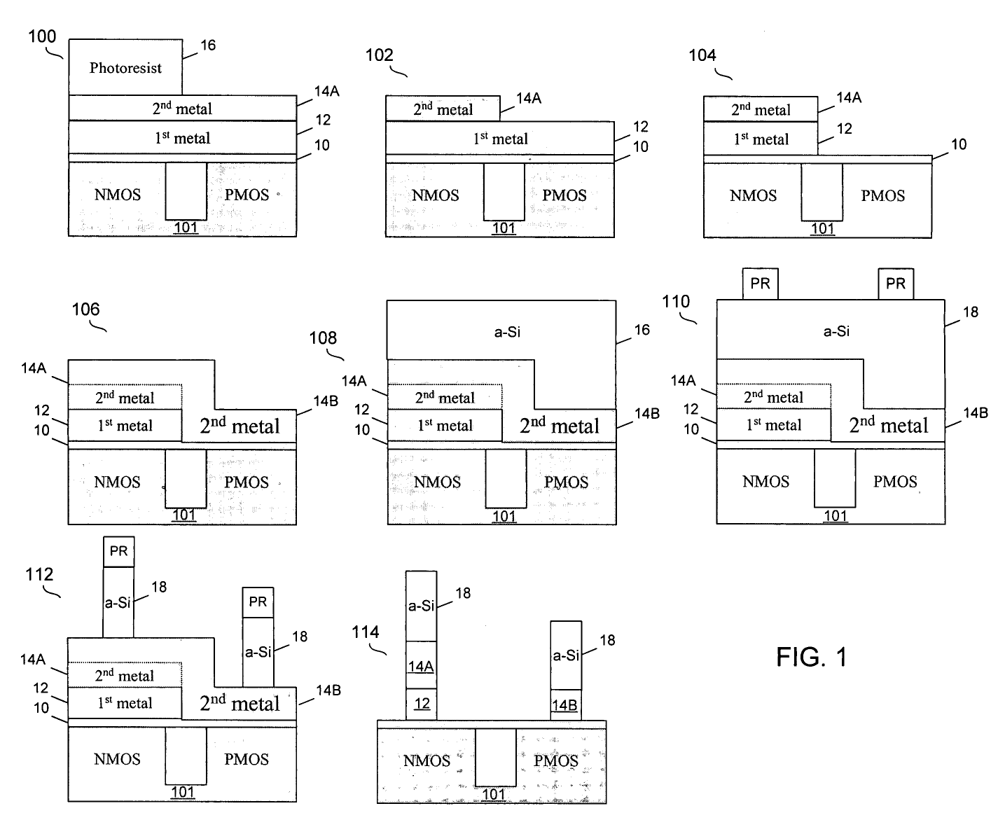

Referring to FIG. 1, a method for fabricating dual metal gate structures on a substrate, such as substrate 101 is shown. Substrate 101 may include an NMOS active region, a PMOS active region, and gate dielectric layer 10. In step 100, a first metal may be deposited to form first metal layer 12 on gate dielectric layer 10. The first metal may include, without limitation, tantalum silicon nitride (TaSiN), titanium nitrate (TiN), tantalum nitride (TaN), hafnium silicon nitride (HfSiN), or titanium silicon nitride (TiSiN), and may form a NMOS metal layer. In some embodiments, the first metal may be deposited using a chemical vapor deposition. Alternatively, other metal deposition techniques, known in the art may be used. For example, atomic layer deposition, e-beam evaporation, filament evaporation, spray coatings, physical vapor deposition, and the like may be used to deposit a metal layer onto gate dielectric 10.

Next, a second metal may be deposited to form second metal layer 14A. The second metal layer may include, without limitation, ruthenium (Ru), molybdenum (Mo), tungsten (W), platinum (Pt), ruthenium oxide (RuO), tungsten nitride (WNₓ), or molybdenum nitride (MoNₓ) and may form a PMOS metal layer. Upon the deposition of the second metal, photoresist layer 16 may be deposited over the entire surface of PMOS metal layer 14A and patterned using techniques known in the art such that the photoresist layer defines the area over the NMOS active region. In step 102, PMOS metal layer 14A may be etched exposing a portion of NMOS metal layer 12. In one embodiment, PMOS metal layer 14A may be etched using a wet chemical etch. Alternatively, the PMOS metal layer may be etched using other known techniques in the art such as, without limitation, chemical etching in liquid and/or gaseous forms, dry etching, or the like.

In step 104, NMOS metal layer 12 may be etched using techniques such as, without limitation, chemical wet etching or dry etching. In one embodiment, PMOS metal layer 14A may serve as a masking layer during the etching process of the NMOS metal layer etch. Since the masking layer has the same material as PMOS metal 14A, the mask layer may be referred to as a homogeneous mask layer. PMOS metal layer 14A may have inert characteristic general to NMOS etch chemistry, and therefore, may be substantially selective during the NMOS metal etch. The etching of NMOS metal layer 12 may expose a portion of gate dielectric 10, particularly the area over the PMOS active region.

Next, a PMOS metal may be deposited over PMOS metal layer 14A and the exposed gate dielectric 10 (resulting from the etching in step 104) to form a second PMOS metal layer 14B, as shown in step 106. In one embodiment, the PMOS metal used to form PMOS metal layer 14B may be the same metal used to form metal layer 14A.

In step 108, a cap, such as, but not limited to, an amorphous silicon cap (denoted a-Si 18 in FIG. 1) may be deposited over the entire device, e.g., PMOS metal layer 14A and 14B. In steps 110-114, the gate stacks are formed. First, a photoresist layer (denoted PR in step 110-114) may be deposited onto a-Si cap 18 to pattern the gate stack, as seen in step 110. During the gate stack etch (step 112), an etching process, selective to PMOS metal layers 14A and 14B may be used to etch a-Si cap 18. As such, the etching process can stop on the metal layers.

After the a-Si cap etching process, a simultaneous etch process, pertinent to both NMOS metal layer 12 and PMOS metal layers 14A and 14B2 may be performed, as seen in step 114. The gate stack etch should stop on gate dielectric layer 10. After gate stack etch, the photoresist layer on top of a-Si 18 may be removed. In one embodiment, the gate stack may be using a plasma etch process. In some embodiments, if Metal-1 and Metal-2 are thin enough, a plasma etch process with a large physical bombardment component may be used to achieve comparable etch rates of the two metal layers. By minimizing the differences between the gate stacks in the NMOS and PMOS regions, the difficulty in gate stack patterning may be significantly reduced.

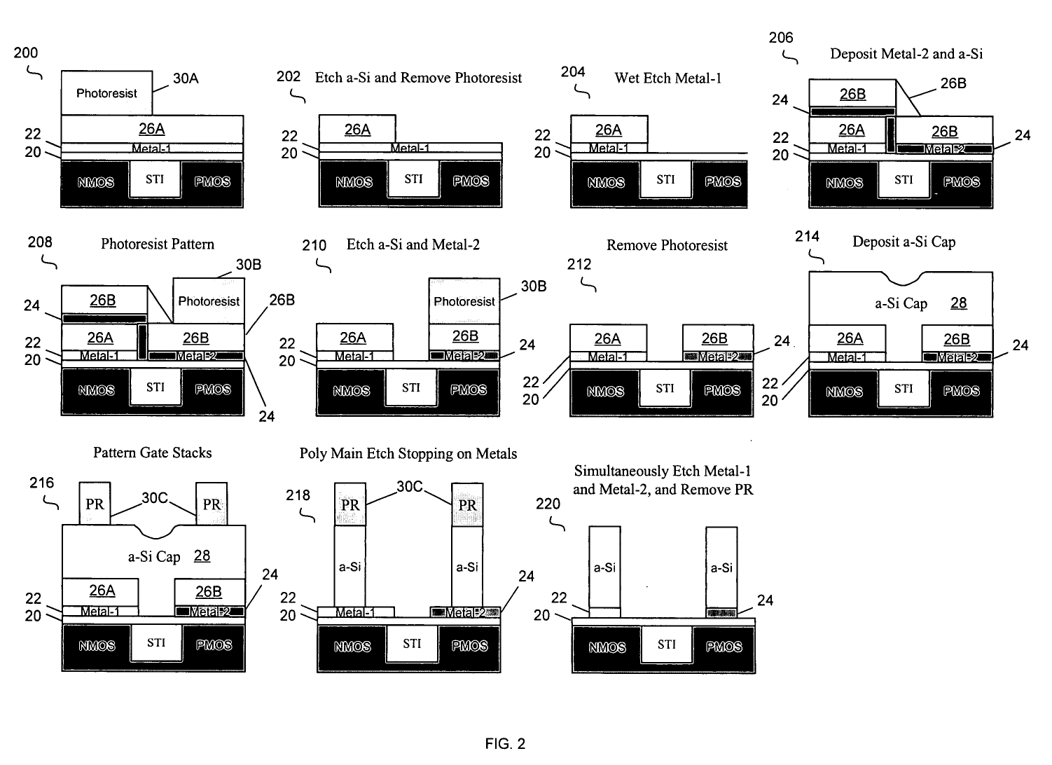

According to other embodiments, a method for fabricating dual metal gate structures is shown in FIG. 2. In step 200, a first metal may be deposited onto gate dielectric 20 to form a first metal layer 22. Next, hardmask 26A may be deposited over first metal layer 22. In one embodiment, hardmask layer 26A may be an amorphous-silicon (a-Si) layer. After the deposition of hardmask layer 26A, photoresist layer 30 may be deposited and patterned over a portion of the hardmask layer. Particularly, photoresist layer 30A may be deposited and patterned over one active region, such as an NMOS active region or a PMOS region. Next, as seen in step 202, hardmask layer 34 may be etched and photoresist layer 30 may subsequently be removed.

In step 204, first metal layer 22 may be etched away for all areas not protected by the hardmask layer to form a first gate area. In one embodiment, a wet-etch process may be used to etch first metal layer 22. It is noted that dry etching may also be used. The type of etching technique, whether by chemical, liquid, or gaseous forms may depend on the metal being etched. In one embodiment, the first metal layer may include a metal compatible with a poly-silicon cap (shown in step 214).

After the etching of first metal layer 22, a second metal may be deposited to form second metal layer 24, as shown in step 206. Unlike conventional methods, hardmask layer 26A used during first metal layer 22 etching process (step 204) remains during this deposition step, and thereby, reduces the impact on the exposed gate dielectric. As such, second metal layer 24 may be deposited over the gate dielectric layer over the PMOS region as well as the hardmask layer 26A and first metal layer 22. Next, second hardmask layer 26B may be deposited over the entire CMOS structure. In one embodiment, second hardmask layer 26B may similar to hardmask layer 26A. For example, hardmask layer 26B may be an amorphous silicon layer.

In step 208, photoresist layer 30B may be deposited and patterned over second metal layer 23 and hardmask layer 26B. In step 210, an etching may be used to remove hardmask layer 26B and another etch process may be used to remove a portion of second metal layer 24. In one embodiment, a wet-etch process may be used to remove second metal layer 24 such that only first metal layer 22 is present in the NMOS region and second metal layer 24 is present in the PMOS region, defining a first and second gate area, respectively. It is noted here that in other embodiments, first metal layer 22 may be present over the PMOS region and second metal layer 24 may be present over the NMOS region.

After the selective etching process, photoresist layer 30B deposited in step 208 may be removed, as seen in step 212. In some embodiments, the photoresist may be removed before the etching of second metal layer 24. As seen in step 212, the gate stacks may have similar thickness and composition over the NMOS and PMOS region. The only difference may be the workfunction of the metal.

In step 214, cap layer 28 may be deposited over the entire device. In steps 216-220, the gate stacks are formed. First, photoresist layer 30C may be deposited and patterned onto cap layer 28, as seen in step 216. During the gate stack etch (step 218), an etching process may be used to etch the hardmask layers 26A and 26B and the cap layer 28. In one embodiment, when hardmask layers 26A and 26B and the cap layer 28 include amorphous silicon, a-Si, the etching process of step 218 may be leave a continuous a-Si layer, as seen in step 218. The etching process of step 218 may be selected such that the etching process stops on metal layers, such as metal gate electrode layers (first metal layer 22 and second metal layer 24). In some embodiments, the thickness of the metal layers may be optimized such that they may be thick enough to set the work functions of the overall gate electrodes and may be thin enough to be easily etched for subsequent metal etch and plasma gate stack etch processes.

After the hardmask and cap etching process, a simultaneous etch process, pertinent to both first metal layer 22 and second metal layer 24 may be performed, as seen in step 220. In one embodiment, a metal or plasma etch process may be used. In some embodiments, if first metal layer 22 and second metal layer 24 are thin enough, a plasma etch process with a large physical bombardment component may be used to achieve comparable etch rates of the two metal layers. By minimizing the differences between the gate stacks in the NMOS and PMOS regions, the difficulty in gate stack patterning may be significantly reduced.

In other embodiments, a flowchart illustrating a method to fabricate dual metal gate is shown. Steps 200 through 212 are similar to the steps of the method shown in FIG. 2. After step 212, the hardmask layers over first metal layer 22 and second metal layer 24 may be removed, leaving only first metal layer (Metal-1) over one active region and second metal layer (Metal-2) over the other active region, as seen in step 220. Next, cap 218 may be deposited may be deposited over the entire device (step 222). In one embodiment, cap 218 may be an amorphous silicon cap. Photoresist layer 30 may next be deposited and patterned such that there may photoresist layer 30 may be over each of the active regions, as shown in step 222. Cap 218 may subsequently be etched (step 224) followed by a simultaneous etch process on both first metal layer (Metal-1) and second metal layer (Metal-2). As seen in step 226, after the removal of photoresist layer 30, a gate stack over the NMOS region and a gate stack over the PMOS region are formed.

The above methods for fabricating dual metal gate stacks for CMOS devices reduce or even substantially eliminate the challenges of the conventional process. First, the differences between the NMOS gate stack and the PMOS gate stack are kept to a minimum allowing for a simple, simultaneous etching process. In one embodiment, the only difference between the NMOS gate stack and the PMOS gate stack is the metal layers. Also, by reducing the number of etching steps, the effect on the gate dielectric layer is minimized, thus reducing the number of defects on a wafer.

All of the methods disclosed and claimed can be made and executed without undue experimentation in light of the present disclosure. While the methods of this invention have been described in terms of embodiments, it will be apparent to those of skill in the art that variations may be applied to the methods and in the steps or in the sequence of steps of the method described herein without departing from the concept, spirit and scope of the invention. All such similar substitutes and modifications apparent to those skilled in the art are deemed to be within the spirit, scope, and concept of the disclosure as defined by the appended claims.

1. A method comprising:
providing a substrate with two active regions and a gate dielectric;
depositing a first metal for forming a first metal layer over the gate dielectric;
depositing a mask layer on the first metal layer;
etching the mask layer exposing a portion of the first metal layer;
etching the exposed portion of the first metal exposing the gate dielectric in area over one of the active regions; and
depositing a second metal on the mask layer and the exposed gate dielectric for forming a second metal layer.

2. The method of claim 1, the mask layer comprising the second metal layer.

3. The method of claim 1, the mask layer comprising an amorphous silicon layer.

4. A method comprising:
providing a substrate with two active regions and a gate dielectric;
depositing a first metal for forming a first metal layer over the gate dielectric;
depositing a second metal for forming a second metal layer directly onto the first metal layer;
depositing a photoresist layer onto the second metal layer;
etching the second metal layer; and
using the etched second metal layer as a masking layer, etching the first metal layer.

5. The method of claim 4, the two active regions comprising an NMOS active region and a PMOS active region.

6. The method of claim 4, the first metal layer comprises a NMOS metal layer.

7. The method of claim 6, the NMOS metal layer being selected from a group consisting of tantalum silicon nitride (TaSiN), titanium nitrate (TiN), hafnium silicon nitride (HfSiN), titanium silicon nitride (TiSiN), and tantalum nitride (TaN).

8. The method of claim 4, the second metal layer comprises a PMOS metal layer.

9. The method of claim 8, the PMOS metal layer being selected from a group consisting of ruthenium (Ru), ruthenium oxide (RuO) molybdenum (Mo), tungsten (W), tungsten nitride (WNₓ), molybdenum nitride (MoNₓ), and platinum (Pt).

10. The method of claim 4, after the step of selectively etching the second metal layer, removing the photoresist layer.

11. The method of claim 4, after the step of selectively etching the first metal layer, depositing more of the second metal onto the two active regions.

12. The method of claim 11, after the step of depositing more of the second metal, depositing a cap layer.

13. The method of claim 12, the cap layer comprising an amorphous-silicon cap.

14. The method of claim 11, after the step of depositing a cap layer, depositing a photoresist layer onto the cap lay and patterning the photoresist layer.

15. The method of claim 14, after the step of patterning the photoresist layer, etching the cap layer to form a first and second gate stack area, where the first gate stack area comprises the first and second metal layer and the second gate stack layer comprises the second metal layer.

16. The method of claim 15, after the step of etching the cap layer, simultaneously etching the first and second metal layer of the first gate stack area to form a first gate stack and etching the second metal layer of the second gate stack area to form a second gate stack

17. The method of claim 16, the first gate stack comprising a gate stack for a NMOS and the second gate stack comprising a gate stack for a PMOS active region.

18. A method for fabricating two metal gate stacks for a complementary metal oxide semiconductor, comprising:
providing a substrate with two active regions and a gate dielectric;
depositing a first metal layer over the gate dielectric;
depositing a first hardmask layer over the first metal layer;
etching the first hardmask layer to an area that covers one of the active regions;
etching the first metal layer for forming a first gate area and exposing a portion of the gate dielectric;
depositing a second metal layer over the first hardmask layer and the exposed portion of the gate dielectric;
depositing a second hardmask layer over the second metal layer;
etching the second hardmask layer to an area that covers the other active region; and
etching the second metal layer for forming a second gate area.

19. The method of claim 18, prior to the step of etching the first hardmask layer, depositing and patterning a first photoresist layer over one of the active region.

20. The method of claim 19, after the step of etching the first hardmask layer, removing the first photoresist layer.

21. The method of claim 18, prior to the step of etching the second hardmask, depositing and patterning a second photoresist layer over one of the active region.

22. The method of claim 21, after the step of etching the second metal layer, removing the second photoresist layer.

23. The method of claim 18, the two active regions comprising an NMOS active region and a PMOS active region.

24. The method of claim 18, the first hardmask layer comprising an amorphous silicon layer.

25. The method of claim 18, the second hardmask layer comprising an amorphous silicon layer.

26. The method of claim 18, further comprising depositing a cap after the step of etching the second metal layer.

27. The method of claim 26, the cap comprising an amorphous silicon cap.

28. The method of claim 26, after depositing the cap, depositing and patterning a third photoresist layer over both active regions.

29. The method of claim 28, after the step of depositing the third photoresist layer, etching the cap and the first and second hardmask layers.

30. The method of claim 29, after the step of etching the cap and first and second hardmask layers, simultaneously etching the first and second metal layers.

31. The method of claim 30, after the step of simultaneously etching the first and second metal layers, removing the third photoresist layer.

32. The method of claim 18, after the step of etching the second metal layer, depositing and patterning a third photoresist layer directly on the first hardmask layer and second hardmask layer.

33. The method of claim 32, after the step depositing the third photoresist layer, etching the first and second hardmask layers.

34. The method of claim 33, after the step of etching the first and second hardmask layers, simultaneously etching the first and second metal layers.
